(19) United States
(12) Patent Application Publication
(10) Pub. No.: US 2026/0088815 A1
(43) Pub. Date: Mar. 26, 2026

(54) CIRCUITRY AND MICROCONTROLLER

(71) Applicant: Infineon Technologies AG, Neubiberg (DE)

(72) Inventors: Stephan LEISENHEIMER, Oberhaching (DE); Severin NEUNER, Valley (DE); Jakob VALTL, München (DE); Matthias ERNST, München (DE); Rainer KLING, Muenchen (DE); Stefan HIEBL, Freising (DE)

(21) Appl. No.: 19/338,875

(22) Filed: Sep. 24, 2025

(30) Foreign Application Priority Data
Sep. 26, 2024 (DE) 102024209348.3

(51) Int. Cl. H03K 17/62; H03K 17/082

(52) U.S. Cl. CPC H03K 17/62; H03K 17/0826; H03K 2217/0063

(57) ABSTRACT

Circuitry in combination with a microcontroller, the circuitry comprising a first transistor and a second transistor, both arranged in series having a signal I/O in between; wherein the first transistor is configured to output a first state to the signal I/O dependent on a first (sensor) signal; wherein the second transistor is configured to output a second state to the signal I/O dependent a second signal; wherein the signal I/O is configured to provide a third state if the first and the second transistors are deactivated.

### CROSS REFERENCE TO RELATED APPLICATION

This application claims priority to Germany Patent Application No. 102024209348.3 filed on Sep. 26, 2024, the content of which is incorporated by reference herein in its entirety.

### FIELD

Implementations of the present implementation refer to a circuitry and especially a sensor circuitry in combination with a microcontroller. Further implementations refer to a method for operating a circuitry and to a method for operating a microcontroller and to a corresponding computer program. Some sensors like magnetic switches are often used in combination with sensor circuitries or integrated in sensor circuitries.

### BACKGROUND

These sensor circuitries enable a chip-to-chip communication. An example is a magnetic switch which is used in a three-pin package. This three-pin package performs chip-to-chip communication with a microcontroller which, for example, collects the sensor signals and determines or monitors a failure status. This can be solved by spending one additional pin. However, this causes additional costs. In other examples, so-called live ticks are used. They are working with a timing scheme wherein this implies a lot of effort on the microcontroller side to continuously measure the time. Therefore, there is a need for an improved approach.

Implementations of the present implementation provide a (sensor) circuitry in combination with a microcontroller. The circuitry comprising a first transistor and a second transistor, both arranged in series having a signal input/output (I/O) of the circuitry in between; the first transistor is configured to output a first state to the signal I/O of the circuitry dependent on a first signal, wherein the second transistor is configured to output a second state to the signal I/O of the circuitry dependent a second signal; the signal I/O of the circuitry is configured to provide a third state if the first and the second transistors are deactivated. The microcontroller comprising a signal I/O of the microcontroller and a third transistor; the signal I/O of the microcontroller comprising an input which is configured to distinct between the first state and the second state or the third state provided by the circuitry via a signal line; here the third transistor is coupled to the signal line via the signal I/O of the microcontroller, wherein the signal I/O of the microcontroller is configured to distinct between the second state and the third state by use of the third transistor.

Another implementation provides a method for operating a circuitry in combination with a microcontroller. The circuitry comprising a first transistor and a second transistor, both arranged in series having a signal I/O of the circuitry in between; the microcontroller comprising a signal I/O of the microcontroller and a third transistor, the signal I/O of the microcontroller comprising an input, wherein the third transistor is coupled to the signal line via the signal I/O of the microcontroller, comprising the following steps: outputting a first state to the signal I/O of the circuitry dependent on a first signal by use of the first transistor; outputting a second state to the signal I/O of the circuitry dependent on a second signal by use of the second transistor; providing a third state if the first and the second transistors are deactivated; and distinguishing between the first state and the second state or the third state provided by the circuitry via a signal line; distinguishing between the second state and the third state by use of the third transistor.

Another implementation provides a computer program for performing, when running a computer, the method as defined above.

Further developments are defined by the subject matter of the dependent claims.

### BRIEF DESCRIPTION OF THE DRAWINGS

Below implementations of the present implementation will subsequently be discussed referring to the enclosed figures, wherein

FIG. 1 exemplarily shows a conventional combination of a sensor circuitry and a microcontroller to illustrate the fundamental principle;

FIG. 2 shows a schematic block diagram of a basic implementation of a sensor circuitry in combination with a according microcontroller to implementations;

FIG. 3A shows a schematic block diagram of an enhanced sensor circuitry according to implementations;

FIG. 3B shows a schematic block diagram of a microcontroller according to implementations;

FIG. 4 shows the combination of the sensor circuitry and the microcontroller according to FIGS. 3A and 3B;

FIG. 5A shows a schematic block diagram of the combination of a sensor circuitry and a microcontroller, where exemplarily failures are illustrated to discuss implementations; and

FIG. 5B shows a schematic matrix illustrating how the failures as illustrated by FIG. 5A can be detected according to implementations.

Below implementations of the present implementation will subsequently be discussed referring to the enclosed figures, wherein identical reference numerals are provided to objects having identical or similar functions so that the description thereof is mutually applicable and interchangeable.

### DETAILED DESCRIPTION

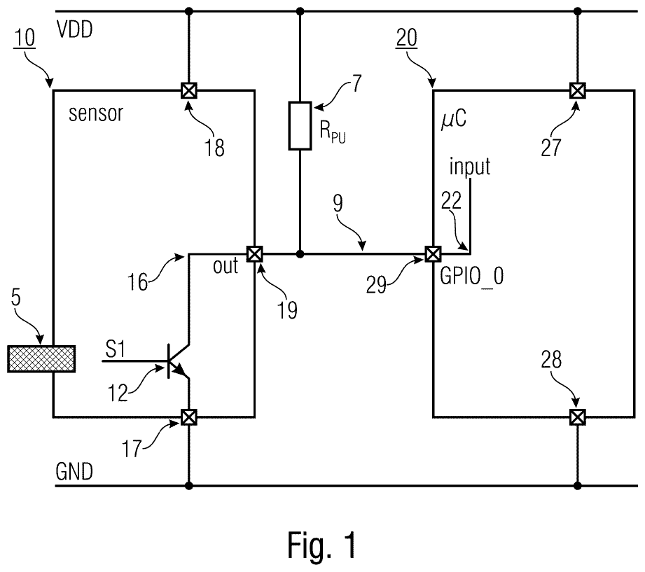

FIG. 1 shows the combination of a sensor circuitry 10 with a microcontroller 20, forming a system. The sensor circuitry is a so-called three pin circuitry 10 which may comprise integrated sensor 5 like a magnetic switch. Here it is assumed that the sensor 5 is integrated into the sensor circuitry 10. A sensor circuitry is coupled via a first pin 17 to ground (GND) (e.g., a reference power supply potential, or ground potential), a second pin 18 to voltage drain drain (VDD) (e.g., a positive power supply potential) and comprises a third pin 19 which forms a signal I/O (signal of input/output) 16 (e.g., a first signal I/O).

The microcontroller 20 is also supplied by GND (cf. pin 28) and VDD (cf. pin 27) and with a third pin 29 to the pin 19 (cf. signal line 9). The microcontroller comprises here a general-purpose input/output 22 (e.g., a second signal I/O). This may, for example, comprise a comparator, so as to differentiate between GND (low) and VDD (high).

The signal line 9 is coupled via a so-called pull up resistor 7 (Rₚᵤ) to VDD.

Regarding the sensor circuit 10 it should be noted that same comprises a transistor 12, e.g., an open drain transistor (S1). For example, the emitter or drain is coupled to 17, wherein the collector is coupled to 19 or the signal input/output. The control contact, like the basis or gate is coupled to the sensor 5.

Since now the structure of the sensor circuit 10 and the microcontroller 12 has been discussed, the functionality will be discussed.

For example, if the sensor 5, e.g., the magnet switch, is closed and/or conducting, the transistor 12 can be closed, wherein the signal input/output 16 is configured to transmit the sensor data from the sensor 5. In this example, the sensor 5 provides data via the open drain (S1) of the transistor 12 and the external pull of resistor 7 to the microcontroller 20. The signal or state applied to the pin 19 is also referred to as first state indicating a closed transistor 12. Of course, the transistor 12 can be closed due to the presence of a signal, e.g., when the sensor 5/magnetic switch is activated. According to further implementations, this can be vice versa so that the transistor 12 is closed when the sensor 5 is deactivated. This depends on the exact implementation of the sensor 5 and the transistor 12, e.g., here as open drain transistor.

The microcontroller 20 comprises a general-purpose input/output (GPIO) 22 which is configured as input. It determines the first state, e.g., by a low signal (lower than a threshold), a current flow or short circuit.

As indicated above, the first state at the pin 19 may, for example, be a ground signal applied to 19, wherein another signal also referred to as third state may be configured as unstable VDD potential. Such a unstable VDD potential, also referred to as high potential, can be pulled too low or ground. For example, the above-mentioned comparator of the GPIO 22 determines a low signal (first state) when the signal at pin 19 is below a threshold, or a high signal (below referred to as third signal), when the signal is above the threshold. For example, the low signal (resulting from a closed transistor 12 setting the potential of 9 to GND) indicates the first state, wherein the high signal (resulting from an open transistor 12, so the pull up resistor 7 defines the potential at signal line 9 as high) indicates a third state. Expressed in other words, this means, that the third state is the signal, where this signal is provided externally (e.g., by an external (external with respect to the sensor circuit 10) component, here the pull up resistor 7 coupled between VDD and signal line 9. According to an implementation, the comparator may comprise a hysteresis.

It is often a problem that on the microcontroller side it is impossible to determine whether the first state results from the sensor 5 applying GND to 19 or whether a failure, e.g., damaged cable, causes this first state signal.

Vice versa, it is often difficult to distinguish between the third state caused by the switching status of the transistor 12 and a broken wiring at the pin 19. For this, the sensor 10 often comprises a kind of microcontroller or diagnosis controller configured to send so-called live ticks. Here, a timing scheme is applied in accordance to same different states, e.g., first or third state are applied to the pin 19. However, implying such time schemes causes a lot of effort on the microcontroller side for continuously measuring the time and/or for synchronizing the sensor circuitry 10 and the microcontroller 20.

Starting from this, the sensor circuitry 10 is—according to implementations-adapted so at to enable to provide another state, e.g., to be used as status for transmitting a diagnosis information, like a status information or failure information. This state is referred to as second state.

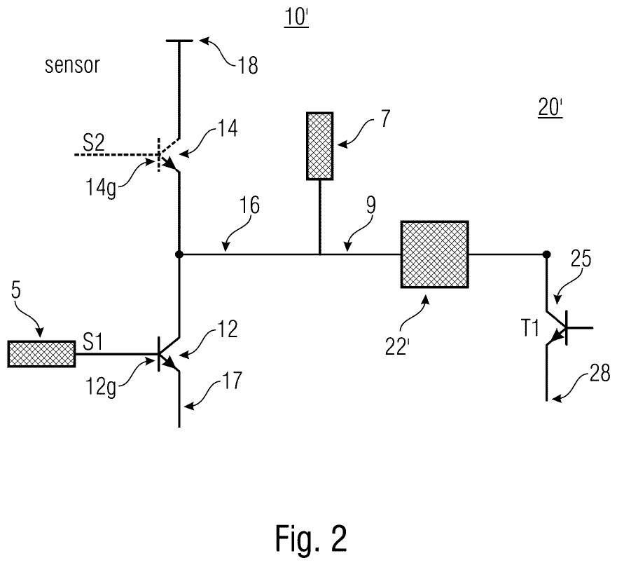

FIG. 2 shows a sensor circuitry 10′ comparable the sensor circuitry 10, but enhanced as follows. The sensor circuitry 10′ comprises in addition to the first transistor 12 and a second transistor 14, wherein the first and the second transistors 12 and 14 are coupled in series having the signal I/O 16 in between. The second transistors 14 is configured to provide the second state.

This sensor circuitry 10′ is read out by a microcontroller 20′. The microcontroller 20′ substantially complies with the microcontroller of 20, but further comprises a third transistor 25. The transistor 25 is coupled between the signal I/O 22′ of the microcontroller 20′ and a first pin 28 having GND (signal of the first state). The transistor 25 in connection with the signal I/O 22′ enables to distinct between a second and third state as provided by the sensor circuitry 10′. Comparable to FIG. 1 the signal line 9 may be coupled to a pull up resistor 7.

In the following, the structure and functionality of the sensor circuitry 10′ will be discussed. The collector contact of the transistor 14 is coupled to the pin 18 while the emitter contact of the transistor 12 is coupled to the pin 17. The emitter contact of 14 is coupled to the collector contact of the transistor 12, and both are coupled to the signal I/O 16. Again, using the control or basis contact of the transistor 12, here marked by the reference number 12g, the sensor signal from the sensor 5 can be received. The transistor 14 receives via its control or basis contact 14g a diagnosis signal, particularly a failure signal or a status signal.

The transistor 12 is a pull low resistor configured to communicate the normal data using the first status (e.g., if it is closed). Here the first status may be GND. Thus, the signal I/O is configured to provide a GND potential (low) in the first state. The second transistor 14 is a pushup transistor configured to provide the second state, e.g., pushup VDD or stable VDD or stable high. The first status and the second status are both activated dependent on the signal applied to the respective control contact 12g and 14g.

If no signal is supplied to 12g and 14g, a third status is provided to the signal I/O 16, for example a pull up VDD or unstable VDD or unstable high. Comparable to the description of circuitry 10 of FIG. 1, this third state signal is dependent on the external component, namely the resistor 7. For this, the pull up resistor 7 as illustrated by FIGS. 1 and 2 is used at the pin 19. Note GND (in general low) and VDD (in general high) are just examples and are interchangeable.

In other words, the circuitry 10′ uses a push-pull stage for providing the three states.

In the following, the microcontroller 20′ will be discussed. It comprises in the basic implementation signal I/O 22′ (comparable to signal I/O 22 of FIG. 1) and the transistor 25. Has already discussed in the context of FIG. 1, the signal I/O 22′ is configured to differentiate between the first state (low) and the third/second state (high), e.g., using the comparator. The transistor 25 can be utilized or controlled by the signal I/O 22′ to differentiate between the second state (push up VDD) and third state (pull up VDD).

The difference between the push up VDD and the pull up VDD is that the second status is a so-called stable state, while the third state is a so-called unstable state. For example, the second state may be a high signal, the first state a low signal and the third state an unstable high signal. The unstable high signal can be pulled to low when 19 is coupled to low, e.g., via the third transistor 25. For the stable high this coupling to low would result in a short circuit which can be detected on the microcontroller side or in a low signal detected by the comparator of 22′. In this way stable high (second stat) and unstable high (third state) can be differentiated from each other. The signal I/O 22′ can, thus, determine the second state if the signal is high, when the transistor 25 is closed. In case the transistor 25 is open it is possible to determine the first or third state (cf. above).

According to implementations, the circuitry 10′ comprising the two transistors 12 and 14, both connected in series to form a common node being connected to a signal I/O 16 between the transistors 12 and 14. The a signal I/O 16 enables to output a first state, a second state and a third state. The first state is output via the signal I/O by use of the first transistor 12 and dependent on the first signal, e.g., from the sensor 5, the second state is provided by use of a second transistor 14 dependent on a second signal via the signal I/O 16. The third state is provided via the signal I/O 16, of the first and the second transistors 12 and 14 are open/deactivated. In the above described implementation, it is assumed that 17 is coupled with low, e.g., ground, while 18 is coupled with high, e.g., VDD. Of course, this might be vice versa, so that 17 is coupled with high or VDD and 18 is coupled to low/GND. Independent from the question whether 7 is coupled to low (GND) or high (VDD), the first and the second state are stable states while the third state is an unstable state according to implementations.

In other words the GPIO 22′ uses a push-pull stage for reading out the three states.

When using circuitry 10′ for transmitting a signal, e.g., a sensor signal from the sensor 5, the first and the third signal represent the two different states of the sensor 5. According to implementations, it is of course possible that instead of a sensor signal another (data) signal can be transmitted. The second signal generated by use of the transistor 14 is according to implementations a status signal, particularly a diagnosis signal or failure signal. However, according to further implementations, it is also possible that another sensor signal can be transmitted using the second status. It is according to further implementations also possible that other signals than sensor signals can be transferred as a first signal or a second signal.

In other words, implementations of the present implementation are based on the principle that on the sensor circuit a combination of open drain with push pull is used to transmit at least two independent signals. This is done by implementing a high side switch 14 at the sensor side to shorten the external pull up resistor 7 used for the open drain communication. On microcontroller side, a the pull down transistor of a GPIO can discover if this high side switch 14 is ON or OFF. This can be used as failure status communication or transmitting a further signal. Beneficially this option can be used to get additional information without spending an additional microcontroller pin (μC-pin).

According to further implementations, the output of the signal I/O 16 of the circuitry 10′, 10″ comprises a third pin 19 (e.g., a positive power supply potential pin) coupled to VDD via a pull-up resistor 7. The resistor 7 defines beneficially the signal belonging to the third state.

According to the implementations, the following operating modes are used:
Mode 1—data transfer from the sensor circuitry 10′ to the microcontroller 20′. In this mode the second transistor 14 (S2) is OFF, e.g., inactive, so the first transistor 12 (S1) may be used to transfer the data from the sensor circuitry 10′ to the microcontroller 20′, as is discussed in context of FIG. 1.
Mode 2—If an error occurs in the sensor circuitry 10′, the first transistor 12 (S1) isswitched OFF and the second transistor 14 (S2) is switched ON. The microcontroller 20′ can recognize this error state (second state) in the sensor circuitry 10′ by switching on the third transistor 25 (T1) (T1=ON):
i. if the signal of line 9 is (still) high=>error
ii. if the signal of line 9 is low=>no error

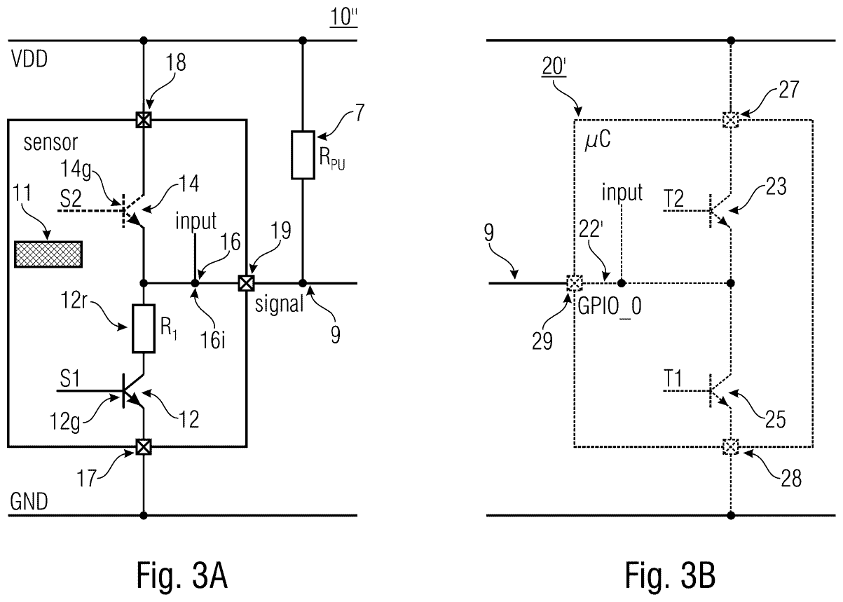

It should be noted, that all details discussed in context of FIG. 1 can according to implementations be applied to the circuitry 10′ and the microcontroller 20′. Below with respect to FIGS. 3A and 3B optional features and further details for the circuitry 10′ and microcontroller 20′ will be discussed.

FIG. 3A shows an enhanced implementation, particularly an enhancement with respect to FIG. 2. Here, the sensor circuit 10″ comprising the three pins 17 coupled to GND, 18 coupled to VDD and 19 coupled to the signal line 9 are present. The sensor circuit 10″ comprises the two transistors 14 and 12 with the control contacts 14g and 12g. Both transistors 14 and 12 are arranged in series having the signal I/O 16 in between. In this implementation, in the node, where the emitter of 14 and the collector of 12 are coupled to each other so as to form the signal I/O, an additional resistor 12r (R₁) is provided between the node and the collector of the transistor 12.

Analogously to the example of FIG. 1 at the signal output line 9 a pull up resistor 7 (R_{PU}) is provided being coupled between 9 and VDD. The implementation of FIG. 3A can be described in other words a follows: a series for the first and second transistor 12 and 14 are arranged between a first pin 17 for applying GND or low and the second pin 19 for applying VDD or high. The signal I/O 16 comprises a third pin being 19 coupled to a VDD via a pull up resistor 7. It should be noted that according to implementations, R₁ of the resistor 12r is smaller than Rₚᵤ of resistor 7.

The transistor 14 (S2) is configured to provide an additional information via the out pin 19 by shortening the pull resistor 7 (Rₚᵤ). Thus, signal S2 can be output via the pin 19. The consequence is that 16 can transmit the first signal S1 as a first state, the second signal S2 as a second state and another signal S3 forming the counterpart of S1 as a third state. According to implementations, the signal I/O 16 is configured to provide a GND or low potential in the first state. According to further implementations the signal I/O 16 is configured to provide a stable VDD potential or stable high in the second state. Note the stable VDD potential may be characterized such that the stable VDD potential cannot be pulled to low. According to further implementations, a signal I/O 16 is configured to provide an unstable VDD potential in a third state or is configured to provide an unstable VDD potential or unstable high in an third state, the unstable VDD potential being characterized such that the unstable VDD (unstable third state in general) can be pulled to low since the potential is provided by the pull up resistor 7 not being bypassed by the second transistor 14.

In other words, this means, according to implementations, the input of the signal I/O 22′ comprises or is coupled a first transistor 25 coupled between the signal I/O 22′ and a first pin 28 having the first state and configured to be closed so as to determine a current flow or in the second or third state. According to further implementations, the input of the signal I/O 22′ comprises is coupled a first transistor 25 coupled between the signal I/O 22′ and a first pin 28 having the first state and configured to be closed so as to determine a current flow in the second or third state and to differentiate between the second and third state dependent on the situation that the third state can be pulled to the first state and/or the second state courses a short circuit.

According to implementations 10″ may comprise a kind of controller performing a diagnosis so as to determine a status or failure of the unit 10″. This status can be output as signal S2 via the transistor 14. For example, in case of a failure S2 is generated so as to provide a signal corresponding to the second state. Preferably, the transistor 12 is open in this situation. According to implementations, the controller 11 can be triggered by a received trigger signal to perform diagnosis. According to implementations, the controller 11 can output a status signal, like a simple acknowledgement signal, in response to the trigger. For example, when the first stage is activated, the controller 11 is configured to output via the second state a signal different from the first state as an acknowledgement. In case the second state or third state is activated the controller can output the second state signal as an acknowledgement. For example, the signal may be limited with regard to its time period, e.g., 100 ms or less. Thus, according to implementations, the trigger signal may be configured to trigger the control 11 for an internal process. Here, the internal process may, for example be defined by:
deactivating or shortly deactivating the first state, e.g., if the first state is active;
activating or shortly activating the second state, e.g., if the first state is active; and
activating or shortly activating the first state, e.g., if the third state is active.

This principle is advantageous, since in this manner the timely scheduled live ticker can be avoided, since the microcontroller can check the live status on request/trigger).

According to implementations, the trigger is received on the circuitry side via the signal I/O 16. For this, the signal I/O 16 comprises an input 16i, e.g., a GPIO which is configured to receive the trigger signal via the signal line 9 and the pin 19. The input 69 of the signal I/O 16 may be connected to the controller 11. According to implementations, 16i is configured to recognize the error check of the microcontroller 20″, e.g., via a trigger like a current flow in transistor 14 (S2). If the sensor circuitry 10′ recognizes the error check, this can be used to start additional processes in the sensor (e.g., output a confirmation pulse). Additionally or alternatively, the sensor circuitry 10′ can be configured in such a way that it recognizes a trigger of T2, e.g., when fourth transistor 23 (T2) is switched ON. This can be done, for example, via the current flow in the sensor through transistor 12 (S1), e.g., to check the connection line 9 between the sensor circuitry 10′ and microcontroller 20″.

FIG. 3B shows the microcontroller 20″ being an enhancement of the microcontroller 20′. It comprises the three pins 27, 28 and 29, wherein, for example, 27 is coupled to VDD or high and 28 is coupled to GND or low. Of course, according to implementations, this may be vice versa. The pin 29 is coupled to the signal line 9 and configured to receive a status signal, e.g., the first status signal, the status signal or the third status signal. This status signal can be determined by use of the GPIO 22′ in combination with two transistors 23 and 25. The transistor 23 (third transistor) and transistor 25 (fourth transistor) are arranged in series between the pins 27 and 28, wherein in between the signal I/O 22′ is arranged. This means that, according to implementations, the control contact of 23 is coupled to 27, wherein the collector of 25 is coupled to 28. The emitter of 23 is coupled to the collector of 25 and via a common node to the signal I/O 22′. By switching the two channels 23 (T2) and 25 (T1) or particularly the channel 25 it is possible to read out the three difference states received via the signal line 9.

For example, the signal detection may be as follows. The second transistor S2 (cf. FIG. 3A) providing the second state can provide the additional information via the output pin by shortening the pull up resistor 7. By switching the transistor 25 (T1) on it is possible to recognize whether S2 is on, e.g., to recognize the second state when a short circuit is caused or when the signal is still high if T1 is closed. The short circuit indicates a stable high signal. This means that the transistor 25 used for reading out the second state provided by the transistor 14 might, according to implementations, have a direct coupling to different potentials high/low. The transistor 25 can be controlled by 22′. Beneficially, a failure status S2 can be provided from the sensor circuit 10″ to the microcontroller 20″ via the output pin. This will be very helpful in products like magnetic switches, e.g., the failure status can be provided without an additional pin.

For the sake of completeness, it should be noted that the transistor 23 (T2) can be used for reading out the first status, e.g., when a current flows from 17 through 12 via 12r, 16, 19, 9 to 29 via 23 to 27. This current flow can be determined by use of 22′. Note the above discussion is made for the case where S2 provides a stable high signal as second state. In case 14 is connected to low, it might provide a stable low signal. In this case, 25 might be connected to high for reading out the stable low signal.

According to implementations a distinction between stable high (second state) and high (third state) can be made by use of the transistor 25 and the signal I/O 22′. It determines a short circuit. In case of a short circuit a stable high is present so that the second state is active. In case there might be a current flow through 22′, but the signal can be pulled to low, an unstable high, e.g., the third state, is present. Thus, a distinction between a solid high and a high state which can be pulled to low by the microcontroller 20″ is made. Expressed in other words this means when the sensor output is high there will always be a current flow as soon as the microcontroller 20″ tries to pull; either via the pull up resistor 7 or the push up transistor 14 there is a large current. Consequently, the three signals high, pull up and low corresponding to second state, third state and first state can be transferred from the circuitry 10″ to 20″ and determined in a distinct manner by the microcontroller 20″.

According to further implementations, wherein the third transistor 25 is configured to be closed, so as to pull a signal from the signal line 9 to the first state if the signal from the signal line 9 is in the third state; additionally or alternatively, the input of the signal I/O 22′ of the microcontroller 20′ is configured to determine the second state if the third transistor 25, which is coupled between the signal I/O 22′ of the microcontroller 20′ and a fist pin 28 having the first state and be closed, does not pull a signal from the signal line 9 to the first state if the signal from the signal line 9 is in the second state.

According to further implementations, the output of 22′ which is configured to output a trigger signal to the circuitry 10′ or 10″ to initiate an internal process or is configured to read out the circuitry 10′, 10″, particularly regarding the activation of the second state.

According to implementations, it might happen that constantly a signal, e.g., the first status is provided. In this case it is beneficial when the controller 20″ is enabled to initiate or trigger an internal process like a diagnosis process. According to implementations, the signal I/O is configured to provide a trigger signal via the pin 29 to the circuitry 10″. For this, a constant high signal by use of the transistor 23 may be provided. Alternatively, a constant low signal by use of the transistor 25 may be applied.

This has the purpose, as already discussed above, to start an internal process like a diagnosis process or to respond with a live signal, e.g., by shortly deactivating the first state and switching to a third state or a second state or by shortly activating the second state. In case the third state or second state is activated, it might also be triggered to shortly activate the first state as a response. When the microcontroller 20″ turns against the detection of a sensor error, the microcontroller 20″ no longer needs to monitor the sensor signal with respect to the time, so that less requirements are needed on the microcontroller side. Consequently, the microcontroller is always in charge.

According to further implementations, the output of the signal I/O 22′ comprises or is coupled a third transistor 25 coupled between the signal I/O 22′ and a first pin 28 having a first state, wherein the trigger comprises outputting the first state by use of the third transistor 25 via the signal I/O 22′. According to further implementations, the output of the signal I/O 22′ comprises or is coupled a fourth transistor 23 coupled between the signal I/O 22′ and a second pin 27 having a second state, wherein the trigger comprises outputting the second state by use of the second transistor 23 via the signal I/O 22′.

According to implementations, signal I/O 22′ is configured to receive as a response to an internal process a feedback via the first or preferably the second or third state. This means that the sensor 10″ responds to the microcontroller 10′ analysis with predefined answer to acknowledge the analysis request (perform diagnosis, like failure detection or detecting).

According to further implementations, the input of the signal I/O 22′ comprises is coupled a fourth transistor 23 coupled between the signal I/O 22′ and a second pin 27 having the second state and configured to be closed, so as to determine the first state if there is a short circuit. Note signal I/O 22′ is configured for receiving and transmitting signals via 19, e.g., comprises an input and an output. the input and the output are both connected to the signal I/O pin 19.

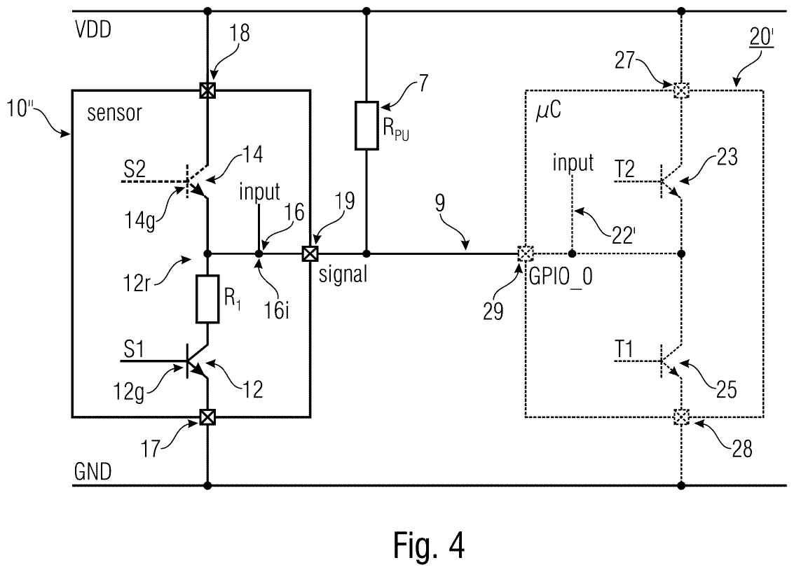

FIG. 4 shows the combination of 10″ and 20″. As can be seen, the signal line 9 connects the pins 19 and 29. In the pin 19 the signal I/O of 10″ is arranged, wherein at the pin 29 the signal I/O of 20″ is arranged.

It should be noted that both on the circuit side of the circuit 10″ and on the microcontroller side of the microcontroller 20″ the signal I/O comprises an input and an output which are both coupled to the single pin 19 and 29, respectively.

As illustrated here by FIG. 4 another implementation provides a system comprising the circuit 10″ and 20″.

As mentioned above, in the dimensions of R₁ and Rₚᵤ it is preferably selected such that R₁ is smaller than Rₚᵤ or significantly smaller. Regarding the transistors 14 and the opposite transistor 25 it should be mentioned that 14 is “stronger” than transistor 25.

The above implementations have the advantage that an additional information, like a diagnosis information, can be transmitted where both the microcontroller 20″ and the circuitry 10″ are based on existing standards.

Also in the above implementations the emitter contacts and collector contacts have been clearly discussed for the circuit 10′ and 10″ and 20″. For example in the discussed implementation bipolar NPN transistors are used. Alternatively, different transistors like PNP may be used as well. For this it should be noted that here the emitter and collector connection might be different, e.g., vice versa. Preferably the control contacts, also referred to as basis contacts, 12g and 14g are connected to the sensors or configured to receive the signal S1 and S2 to be transmitted. According to alternative implementations, different transistors like FETs having a source contact instead of a collector, a gate contact instead of a basis (general control contact) and a drain contact instead of a emitter may be used.

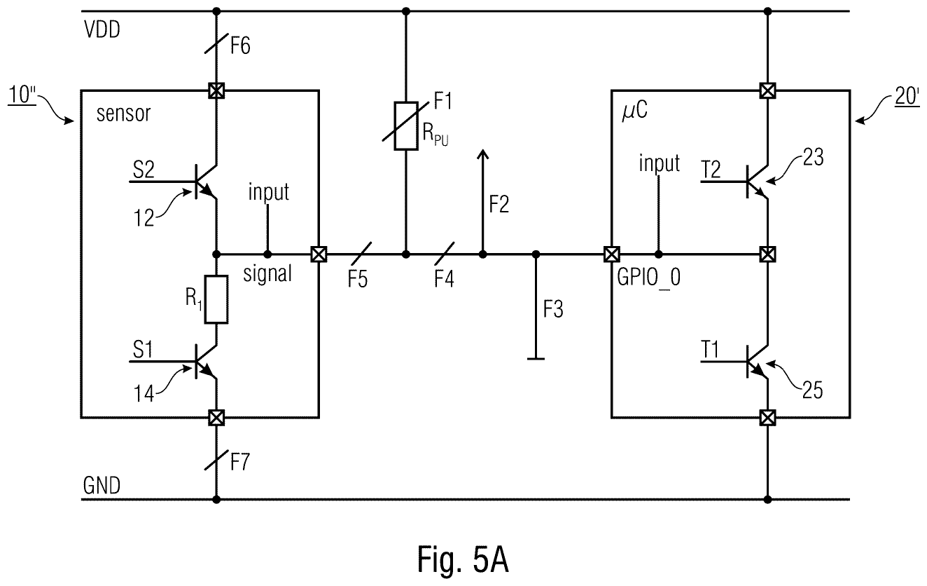

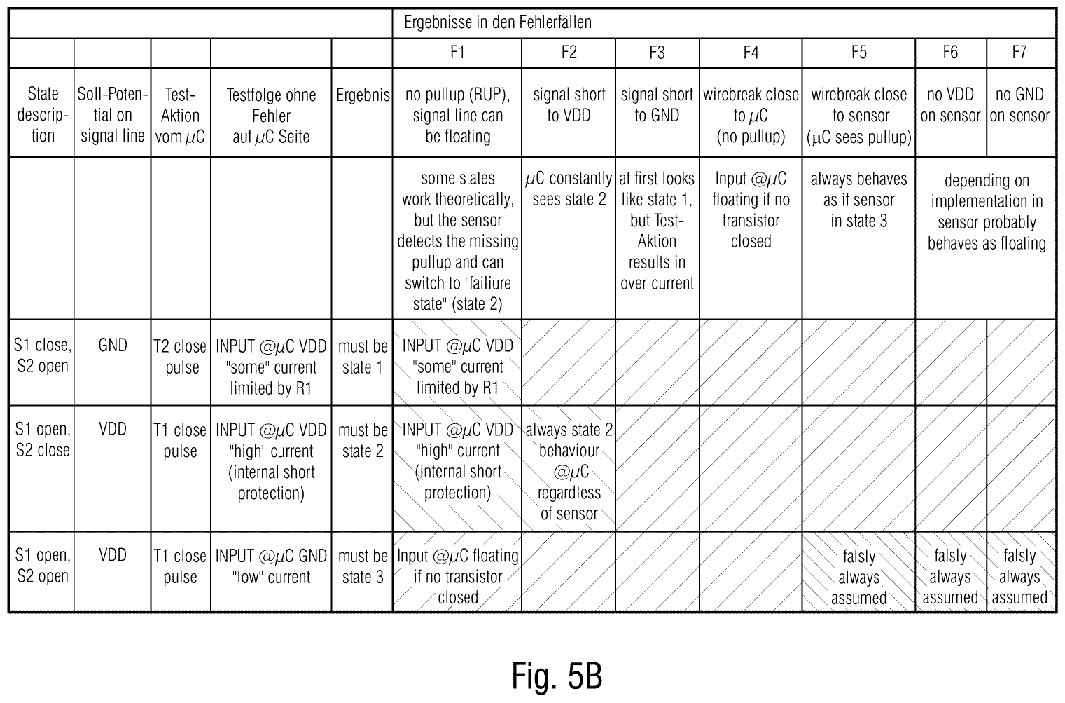

With respect to FIGS. 5A and 5B seven different phases will be discussed. FIG. 5A shows the system of FIG. 4, wherein the failures F1 to F7 are illustrated. According to failure 1 the line for the pull up resistor 7 is broken. According to failure F2, the signal line 9 is connected to VDD. According to failure F3 the signal line 9 is set to GND. According to F4 the signal line 9 is broken. According to F5, the signal line is broken next to the pin 19. According to F6, the FDD line is broken on the sensor side at pin 18. According to failure F7 the GND line is broken at pin 17. FIG. 5 shows the possible combination of situations for detecting F1 to F7.

Below, potential triggers are discussed dependent on the open/closed state of S1 and S2. For S1 closed and S2 open, a T2 closed pulse may be sent, so that state 1, also referred as first state is generated. In case of correct function at the input of 20″, some current, but limited by R₁ is obtained. In case, S1 is open and S2 is closed, a T1 closed pulse might be sent, so that the second state, also referred to as the state 2, is generated. In case of correct function at the microcontroller 20″ input, a high current can be detected, so that the internal short protection might be activated. In case S1 is open and S2 is open, a T1 closed pulse can be sent, so that the state 3, also referred to as third state is generated. The result indicating a correct function is, that a low current is detected at the input of the microcontroller 20″. All these three different triggers and expected responses enable to determine some of above-mentioned failures. Particularly failure F1, F2, F5, F6 and F7 can be detected dependent on the state S1, S2 as illustrated by the matrix of FIG. 5. The light hatched fields indicate that in such cases falsely is always assumed, the sounds without hatching, indicates, that the failure detection is not possible.

For example, for failure F1, no pull-up signal line can be floating. Here, some states may work theoretically, but the sensor detects a missing pull-up and can switch to failure state 2. To determine this failure a differentiation between different states is done. In case S1 is closed and S2 is open, the current which flows to the input 22′ of the microcontroller 20″ is limited by R₁. In case S1 is open and S2 is closed, the current which flows to the input 22′ of the microcontroller 20″ is high, so that an internal shortcut protection might be activated. In case, S1 is open and S2 is open, a floating at the microcontroller 20″ may result, if no transistor is closed.

In case of failure F2, a good detection is possible if S1 is open and S2 is closed. In this case, the second state behavior can be determined if the microcontroller 20″ determines at its input 22′ a second state behavior regardless of the sensor signal.

Although some aspects have been described in the context of an apparatus, it is clear that these aspects also represent a description of the corresponding method, where a block or device corresponds to a method step or a feature of a method step. Analogously, aspects described in the context of a method step also represent a description of a corresponding block or item or feature of a corresponding apparatus. Some or all of the method steps may be executed by (or using) a hardware apparatus, like for example, a microprocessor, a programmable computer or an electronic circuit. In some implementations, some one or more of the most important method steps may be executed by such an apparatus.

Depending on certain implementation requirements, implementations of the implementation can be implemented in hardware or in software. The implementation can be performed using a digital storage medium, for example a floppy disk, a DVD, a Blu-Ray, a CD, a ROM, a PROM, an EPROM, an EEPROM or a FLASH memory, having electronically readable control signals stored thereon, which cooperate (or are capable of cooperating) with a programmable computer system such that the respective method is performed. Therefore, the digital storage medium may be computer readable.

Some implementations according to the implementation comprise a data carrier having electronically readable control signals, which are capable of cooperating with a programmable computer system, such that one of the methods described herein is performed.

Generally, implementations of the present implementation can be implemented as a computer program product with a program code, the program code being operative for performing one of the methods when the computer program product runs on a computer. The program code may for example be stored on a machine readable carrier.

Other implementations comprise the computer program for performing one of the methods described herein, stored on a machine readable carrier.

In other words, an implementation of the inventive method is, therefore, a computer program having a program code for performing one of the methods described herein, when the computer program runs on a computer.

A further implementation of the inventive methods is, therefore, a data carrier (or a digital storage medium, or a computer-readable medium) comprising, recorded thereon, the computer program for performing one of the methods described herein. The data carrier, the digital storage medium or the recorded medium are typically tangible and/or non-transitionary.

A further implementation of the inventive method is, therefore, a data stream or a sequence of signals representing the computer program for performing one of the methods described herein. The data stream or the sequence of signals may for example be configured to be transferred via a data communication connection, for example via the Internet.

A further implementation comprises a processing means, for example a computer, or a programmable logic device, configured to or adapted to perform one of the methods described herein.

A further implementation comprises a computer having installed thereon the computer program for performing one of the methods described herein.

A further implementation according to the implementation comprises an apparatus or a system configured to transfer (for example, electronically or optically) a computer program for performing one of the methods described herein to a receiver. The receiver may, for example, be a computer, a mobile device, a memory device or the like. The apparatus or system may, for example, comprise a file server for transferring the computer program to the receiver.

In some implementations, a programmable logic device (for example a field programmable gate array) may be used to perform some or all of the functionalities of the methods described herein. In some implementations, a field programmable gate array may cooperate with a microprocessor in order to perform one of the methods described herein. Generally, the methods are preferably performed by any hardware apparatus.

The above described implementations are merely illustrative for the principles of the present implementation. It is understood that modifications and variations of the arrangements and the details described herein will be apparent to others skilled in the art. It is the intent, therefore, to be limited only by the scope of the impending patent claims and not by the specific details presented by way of description and explanation of the implementations herein.

### ASPECTS

The following provides an overview of some Aspects of the present disclosure:

Aspect 1: A system, comprising: circuitry; and a microcontroller, wherein the circuitry comprises: a first transistor and a second transistor, both arranged in series having a signal input/output (I/O) of the circuitry in between, wherein the first transistor is configured to output a first state to the signal I/O of the circuitry dependent on a first signal, wherein the second transistor is configured to output a second state to the signal I/O of the circuitry dependent on a second signal, and wherein the signal I/O of the circuitry is configured to provide a third state if the first transistor and the second transistor are deactivated, wherein the microcontroller comprises: a signal I/O of the microcontroller and a third transistor, the signal I/O of the microcontroller comprising an input which is configured to distinguish between the first state and the second state or the third state provided by the circuitry via a signal line, wherein the third transistor is coupled to the signal line via the signal I/O of the microcontroller, and wherein the signal I/O of the microcontroller is configured to distinguish between the second state and the third state by use of the third transistor.

Aspect 2: The system according to Aspect 1, wherein the second signal comprises a status signal, particularly a diagnoses signal or failure signal.

Aspect 3: The system according to any of Aspects 1-2, wherein the first signal comprises a sensor signal, especially a magnetic sensor signal.

Aspect 4: The system according to any of Aspects 1-3, wherein the signal I/O of the circuitry comprises a third pin coupled to a positive power supply potential via a pull-up resistor.

Aspect 5: The system according to any of Aspects 1-4, wherein the third transistor is coupled between the signal I/O of the microcontroller and a fist pin having the first state and configured to be closed, so as to pull a signal from the signal line to the first state if the signal from the signal line is in the third state; and/or wherein the input of the signal I/O of the microcontroller is configured to determine the second state if the third transistor, which is coupled between the signal I/O of the microcontroller and a fist pin having the first state and be closed, does not pull a signal from the signal line to the first state if the signal from the signal line (9) is in the second state.

Aspect 6: The system according to any of Aspects 1-5, wherein the signal I/O of the circuitry is configured to provide a stable positive power supply potential in the second state, the stable positive power supply potential being characterized by that the stable positive power supply potential cannot be pulled to low by the third transistor; and/or wherein the signal I/O of the circuitry is configured to provide an unstable positive power supply potential in the third state, the unstable positive power supply potential being characterized by that the unstable positive power supply potential is provided by a pull up resistor not being bypassed by the second transistor or can be pulled to low by the third transistor.

Aspect 7: The system according to any of Aspects 1-6, wherein the first transistor and the second transistor are arranged, in series, between a first pin for applying a ground potential and a second pin for applying a positive power supply potential.

Aspect 8: The system according to any of Aspects 1-7, wherein the second signal and/or the first signal is applied to a control contact of the first transistor and/or the second transistor.

Aspect 9: The system according to any of Aspects 1-8, wherein a drain or emitter contact of the first transistor is coupled to a first pin; and/or wherein a source or collector contact of the second transistor is coupled to a second pin; and/or wherein a source or collector contact of the first pin is coupled to a drain or emitter contact of the second transistor.

Aspect 10: The system according to any of Aspects 1-9, further comprising: a controller configured to determine a status, particularly a diagnosis status or failure status, and/or being connected to the second transistor and configured to provide the second signal.

Aspect 11: The system according to Aspect 10, wherein the signal I/O of the circuitry is configured to receive a trigger signal, particularly via a third pin; wherein the trigger signal is configured to trigger the controller for an internal process.

Aspect 12: The system according to Aspect 11, wherein the internal process is one of the following: deactivating or shortly deactivating the first state, if the first state is active; activating or shortly activating the second state, if the first state is active; or activating or shortly activating the first state, if the third state is active.

Aspect 13: The system according to any of Aspects 1-12, wherein the signal I/O of the microcontroller comprises an output, which is configured to output a trigger signal to the circuitry to initiate an internal process or which is configured to read out the circuitry, particularly regarding the second state.

Aspect 14: The system according to Aspect 13, wherein the output of the signal I/O of the microcontroller is coupled to a forth transistor which is coupled between the signal I/O of the microcontroller and a second pin having a second state, wherein a trigger comprises outputting the second state by use of the second transistor via the signal I/O of the microcontroller; or wherein the output of the signal I/O of the microcontroller is coupled to a third transistor which is coupled between the signal I/O of the microcontroller and a first pin having a first state, wherein a trigger comprises outputting the first state by use of the first transistor via the signal I/O of the microcontroller.

Aspect 15: The system according to Aspect 11, wherein the circuitry is configured to receive, as a response to the trigger or to the internal process, a feedback via the first state or the second state or the third state.

Aspect 16: A method for operating a circuitry in combination with a microcontroller, the circuitry comprising a first transistor and a second transistor, both arranged in series having a signal input/output (I/O) of the circuitry in between, the microcontroller comprising a signal I/O of the microcontroller and a third transistor, the signal I/O of the microcontroller comprising an input, wherein the third transistor is coupled to a signal line via the signal I/O of the microcontroller, the method comprising: outputting a first state to the signal I/O of the circuitry dependent on a first signal by use of the first transistor; outputting a second state to the signal I/O of the circuitry dependent on a second signal by use of the second transistor; providing a third state if the first and the second transistors are deactivated; distinguishing between the first state and the second state or the third state provided by the circuitry via a signal line; and distinguishing between the second state and the third state by use of the third transistor.

Aspect 17: A non-transitory computer-readable medium having computer-readable instructions stored thereon which when executed by a computer system cause the computer system to perform a method for operating a circuitry in combination with a microcontroller, the circuitry comprising a first transistor and a second transistor, both arranged in series having a signal input/output (I/O) of the circuitry in between, the microcontroller comprising a signal I/O of the microcontroller and a third transistor, the signal I/O of the microcontroller comprising an input, wherein the third transistor is coupled to the signal line via the signal I/O of the microcontroller, the method comprising: outputting a first state to the signal I/O of the circuitry dependent on a first signal by use of the first transistor; outputting a second state to the signal I/O of the circuitry dependent on a second signal by use of the second transistor; providing a third state if the first and the second transistors are deactivated; distinguishing between the first state and the second state or the third state provided by the circuitry via a signal line; and distinguishing between the second state and the third start by use of the third transistor.

Aspect 18: A system configured to perform one or more operations recited in one or more of Aspects 1-17.

Aspect 19: An apparatus comprising means for performing one or more operations recited in one or more of Aspects 1-17.

Aspect 20: A non-transitory computer-readable medium storing a set of instructions, the set of instructions comprising one or more instructions that, when executed by a device, cause the device to perform one or more operations recited in one or more of Aspects 1-17.

Aspect 21: A computer program product comprising instructions or code for executing one or more operations recited in one or more of Aspects 1-17.

1. A system, comprising:
circuitry; and
a microcontroller,
wherein the circuitry comprises:
a first transistor and a second transistor, both arranged in series having a signal input/output (I/O) of the circuitry in between.
wherein the first transistor is configured to output a first state to the signal I/O of the circuitry dependent on a first signal,
wherein the second transistor is configured to output a second state to the signal I/O of the circuitry dependent on a second signal, and
wherein the signal I/O of the circuitry is configured to provide a third state if the first transistor and the second transistor are deactivated,
wherein the microcontroller comprises:
a signal I/O of the microcontroller and a third transistor the signal I/O of the microcontroller comprising an input which is configured to distinguish between the first state and the second state or the third state provided by the circuitry via a signal line,
wherein the third transistor is coupled to the signal line via the signal I/O of the microcontroller, and
wherein the signal I/O of the microcontroller is configured to distinguish between the second state and the third state by use of the third transistor.

2. The system according to claim 1, wherein the second signal comprises a status signal, particularly a diagnoses signal or failure signal.

3. The system according to claim 1, wherein the first signal comprises a sensor signal, especially a magnetic sensor signal.

4. The system according to claim 1, wherein the signal I/O of the circuitry, comprises a third pin coupled to a positive power supply potential via a pull-up resistor.

5. The system according to claim 1, wherein the third transistor is coupled between the signal I/O of the microcontroller and a fist pin having the first state and configured to be closed, so as to pull a signal from the signal line to the first state if the signal from the signal line is in the third state; and/or
wherein the input of the signal I/O of the microcontroller is configured to determine the second state if the third transistor, which is coupled between the signal I/O of the microcontroller and a fist pin having the first state and be closed, does not pull a signal from the signal line to the first state if the signal from the signal line (9) is in the second state.

6. The system according to claim 1, wherein the signal I/O of the circuitry is configured to provide a stable positive power supply potential in the second state, the stable positive power supply potential being characterized by that the stable positive power supply potential cannot be pulled to low by the third transistor; and/or
wherein the signal I/O of the circuitry is configured to provide an unstable positive power supply potential in the third state, the unstable positive power supply potential being characterized by that the unstable positive power supply potential is provided by a pull up resistor not being bypassed by the second transistor or can be pulled to low by the third transistor.

7. The system according to claim 1, wherein the first transistor and the second transistor are arranged, in series, between a first pin for applying a ground potential and a second pin for applying a positive power supply potential.

8. The system according to claim 1, wherein the second signal and/or the first signal is applied to a control contact of the first transistor and/or the second transistor.

9. The system according to claim 1, wherein a drain or emitter contact of the first transistor is coupled to a first pin; and/or
wherein a source or collector contact of the second transistor is coupled to a second pin; and/or
wherein a source or collector contact of the first pin is coupled to a drain or emitter contact of the second transistor.

10. The system according to claim 1, further comprising:
a controller configured to determine a status, particularly a diagnosis status or failure status, and/or being connected to the second transistor and configured to provide the second signal.

11. The system according to claim 10, wherein the signal I/O of the circuitry is configured to receive a trigger signal, particularly via a third pin;
wherein the trigger signal is configured to trigger the controller for an internal process.

12. The system according to claim 11, wherein the internal process is one of the following:
deactivating or shortly deactivating the first state, if the first state is active;
activating or shortly activating the second state, if the first state is active; or
activating or shortly activating the first state, if the third state is active.

13. The system according to claim 1, wherein the signal I/O of the microcontroller comprises an output, which is configured to output a trigger signal to the circuitry to initiate an internal process or which is configured to read out the circuitry particularly regarding the second state.

14. The system according to claim 13, wherein the output of the signal I/O of the microcontroller is coupled to a forth transistor which is coupled between the signal I/O of the microcontroller and a second pin having a second state, wherein a trigger comprises outputting the second state by use of the second transistor via the signal I/O of the microcontroller; or
wherein the output of the signal I/O of the microcontroller is coupled to a third transistor which is coupled between the signal I/O of the microcontroller and a first pin having a first state, wherein a trigger comprises outputting the first state by use of the first transistor via the signal I/O of the microcontroller.

15. The system according to claim 11, wherein the circuitry is configured to receive, as a response to the trigger or to the internal process, a feedback via the first state or the second state or the third state.

16. A method for operating a circuitry in combination with a microcontroller, the circuitry comprising a first transistor and a second transistor, both arranged in series having a signal input/output (I/O) of the circuitry in between, the microcontroller comprising a signal I/O of the microcontroller and a third transistor, the signal I/O of the microcontroller comprising an input, wherein the third transistor is coupled to a signal line via the signal I/O of the microcontroller the method comprising:
outputting a first state to the signal I/O of the circuitry dependent on a first signal by use of the first transistor;
outputting a second state to the signal I/O of the circuitry dependent on a second signal by use of the second transistor;
providing a third state if the first and the second transistors are deactivated;
distinguishing between the first state and the second state or the third state provided by the circuitry via a signal line; and
distinguishing between the second state and the third state by use of the third transistor.

17. A non-transitory computer-readable medium having computer-readable instructions stored thereon which when executed by a computer system cause the computer system to perform a method for operating a circuitry in combination with a microcontroller, the circuitry comprising a first transistor and a second transistor, both arranged in series having a signal input/output (I/O) of the circuitry in between, the microcontroller comprising a signal I/O of the microcontroller and a third transistor, the signal I/O of the microcontroller comprising an input, wherein the third transistor is coupled to the signal line via the signal I/O of the microcontroller, the method comprising:
outputting a first state to the signal I/O of the circuitry dependent on a first signal by use of the first transistor;
outputting a second state to the signal I/O of the circuitry dependent on a second signal by use of the second transistor;
providing a third state if the first and the second transistors are deactivated;
distinguishing between the first state and the second state or the third state provided by the circuitry via a signal line; and
distinguishing between the second state and the third start by use of the third transistor.
